(19) United States
(12) Patent Application Publication
(10) Pub. No.: US 2004/0217449 A1
(43) Pub. Date: Nov. 4, 2004

(54) Electronic component packaging

(75) Inventor: Janet Suzanne Patterson, San Diego, CA (US)

Correspondence Address: FOLEY & LARDNER, P.O. BOX 80278, SAN DIEGO, CA, 92138-0278, US

(73) Assignee: Maxwell Electronic Components Group, Inc.

(21) Appl. No.: 10/427,608

(22) Filed: Apr. 30, 2003

(51) Int. Cl. H01L 23/495

(52) U.S. Cl. 257/666

(57) ABSTRACT

An electronic component package and a method of forming the package are disclosed. The package includes a die having a top face with set of contacts and a substrate having a cutout therein. The die may include a memory component and may include SDRAM. The substrate is mounted on the top face, and the cutout overlays the set of contacts. Wire leads extend from the set of contacts, at least partially through the cutout, to the substrate. The set of contacts may be positioned along a central region of the die, and the cutout overlays the central region. The wire leads extend to the substrate and may contact the substrate proximate to the cutout. The package may further include a set of electrical paths extending from the wire leads through the substrate for providing communicative path between the die and an external component.

### FIELD OF THE INVENTION

The present invention relates generally to electronic components. More particularly, the invention relates to packaging for electronic components.

### BACKGROUND

The following description is provided to assist the understanding of the reader. None of the information provided or references cited is admitted to be prior art to the present invention.

Many electronic components, particularly computer components, are provided with contacts for making electrical connections to other components for receiving or transmitting inputs, outputs, electrical power or other signals. For example, most computer chips include a die having a set of contacts, and are provided with a number of pins extending from the contacts for connecting the chip to a board. The die contains the internal microcircuitry for operation of the chip. Signals are directed to and from the die through the pins for communication with an external component. This configuration is commonly found in many types of computer components such as processors and memory chips.

In some applications, a lead frame is mounted to the die to direct signals to and form the contacts. The lead frame is typically a rigid, integrally formed set of leads made from a conductive material such as copper. Electrical connection from the die to the set of leads is typically made by wire. The lead frame includes a set of rigid leads leading from the contacts of the die to an external component. The lead frame and die may be formed as a package through encapsulation of the die in a housing through which the rigid leads extend. FIG. 1 illustrates an example of such an arrangement. The package 100 includes a die 102 having a set of contacts 104. A rigid lead from 106 is mounted above the die 102 to provide electrical communication between the die 102 and an external component (not shown). The die contacts 104 are connected to the rigid lead by a wire 105. The die 102 is encompassed in a housing 108. The housing may be made of any of a variety of materials, but plastic is commonly used. The leads of the lead frame 106 extend through the housing, allowing communication with external components.

Although the housing 108 can provide substantial protection for the die from the environment, its protective abilities are limited. In certain applications, such as uses in a space environment, the die may be required to be hermetically sealed from the external environment while still allowing for electrical communication with external components. For such applications, as illustrated in FIG. 2A, the die 202 may be mounted on a nonconductive substrate 206 with wire-bond connections 208 between the contacts 204 of the die 202 and contacts on the substrate 206. The die 202 is mounted with its backside adjacent to the substrate 206. This substrate 206 is then attached to a package 209 in which the contacts on the substrate 206 are attached with a set of wires 210 to an internal circuitry in the package, allowing electrical communication between the die and any external components through one or more package leads 212. In other applications, as illustrated in FIG. 2B, the backside of the die 202 may be directly attached to a package 209. The contacts 204 of the die 202 are then wirebonded directly to the package 209 and then routed via internal circuitry to the external package pins or lead 212. In both of these applications, the package can then be hermetically sealed, protecting the die and wirebonds from environmental damage.

For some electrical components, the contacts may be located along a central region, rather than the perimeter, of the die. For example, a typical Synchronous Dynamic Random Access Memory (SDRAM) die includes contacts along the center of the die to facilitate faster operation and timing of the device. As a result, the wires must extend from the central region of the die to a point on the substrate beyond the perimeter of the die, as shown in FIG. 2. This results in longer wires, which may cause unacceptable levels of inductance and resistance. Further, the longer wires increase the likelihood of two adjacent wires shorting due to a swaying, or sweeping of the wires.

It is desirable to achieve an electronic component package or method of packaging which allows for use of wire-bonding such components without the increase in inductance, resistance and sweeping.

### SUMMARY OF THE INVENTION

The invention described herein relates to packaging of electronic components. The invention provides for arrangements of an electronic component die within a package which allows the use of shorter wire lengths for wire bonding regardless of the position of the contacts on the die.

In one aspect, the invention provides an electronic component package including a die having a top face with set of contacts, and a substrate having a cutout therein. The substrate is mounted on the top face, and the cutout overlays the set of contacts. The package further includes wire leads extending from the set of contacts, at least partially through the cutout, to the substrate.

The electronic component may be any component requiring electrical communication with an external component or environment. The electrical communication may include sending signals, receiving signals or receipt or transmission of electrical power. The substrate may be made of any non-conductive material such as a ceramic. Wire leads are made of a conductive material such as aluminum. The thickness of the wire leads may be selected according to the requirements of the system.

In a preferred embodiment, the set of contacts is positioned along a central region of said die. The cutout overlays the central region.

The wire leads may extend to the substrate and contact the substrate proximate to the cutout. The package may further include a set of electrical paths extending from the wire leads through the substrate for providing communicative path between the die and an external component.

In a preferred embodiment, the die includes a memory component. In a still further preferred embodiment, the memory component is an SDRAM. The set of contacts may be positioned along a central region of the die, and the cutout may overlay the central region.

In another aspect, the invention provides a method of forming an electronic component package. The method includes mounting a substrate on a top face of a die. The top face has a set of contacts, and the substrate has a cutout therein. The cutout overlays the set of contacts. The method also includes extending wire leads from the set of contacts, at least partially through the cutout, to the substrate.

While aspects and embodiments of the present invention are described herein, it would be understood that such descriptions are exemplary of uses and aspects of the presently described error detection and correction systems and methods and should not be limiting in content.

### DESCRIPTION OF DRAWINGS

FIG. 1 is a cross-sectional view of a prior art electronic component package;

FIGS. 2A and 2B are perspective views of additional prior art electronic component packages;

FIG. 3 is a perspective view of an electronic component package according to an embodiment of the present invention; and

FIG. 4 is a cross-sectional view taken along IV-IV of FIG. 3.

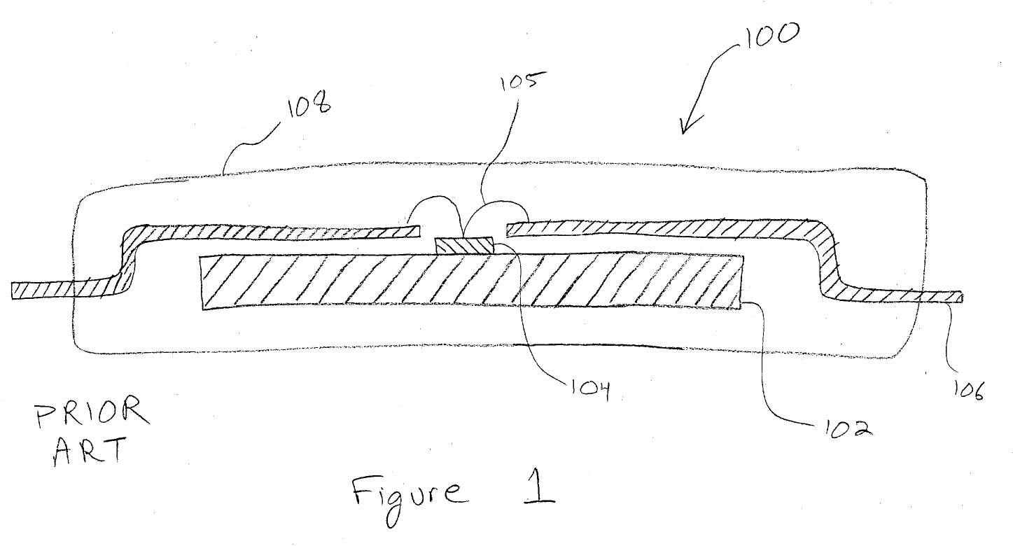

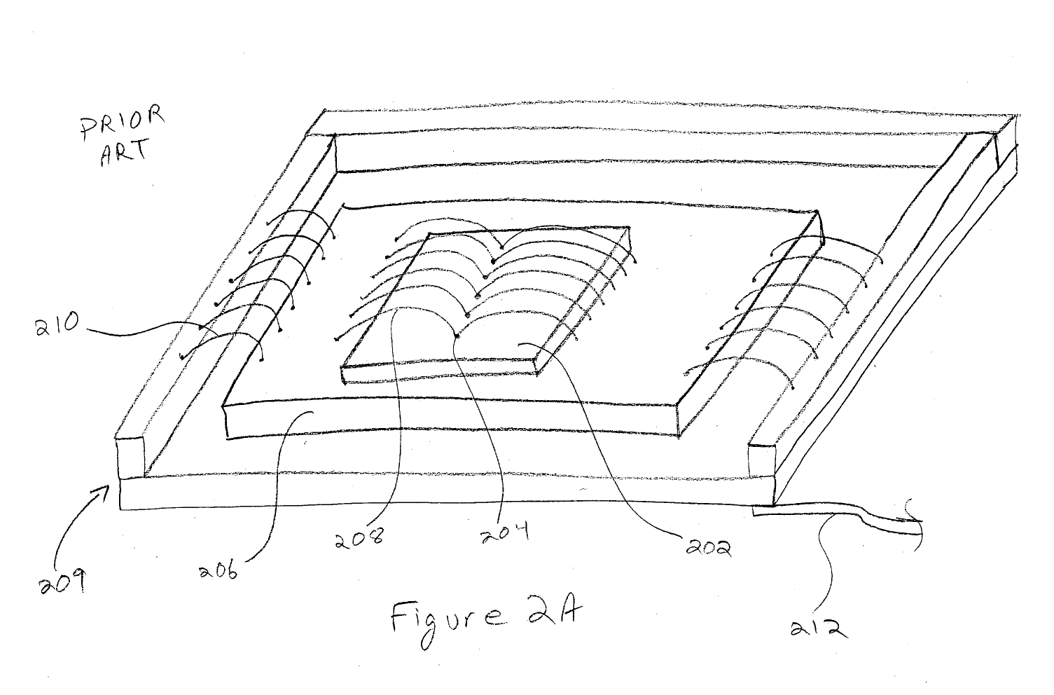

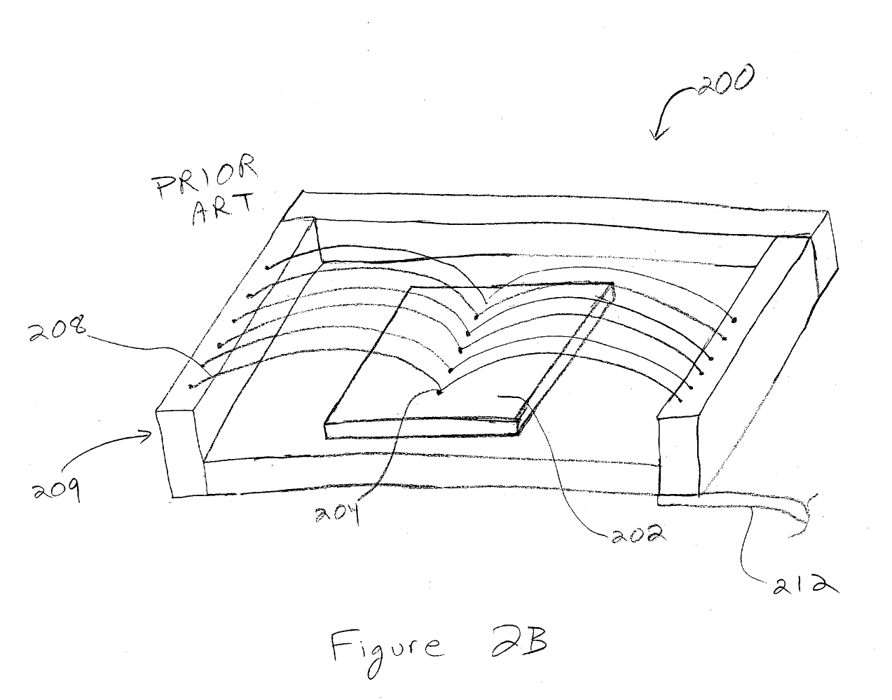

### DETAILED DESCRIPTION

The present invention is generally directed to packaging of an electronic component, such as a memory die. The present invention allows for use of wire bonding for providing electrical communication between the electronic component and an external component or environment without an undesirable increase in inductance, impedance and sweeping.

The disclosed implementation of an electronic component package uses an arrangement which allows the use of shortened wire lengths to provide electrical communication between the die and an external component.

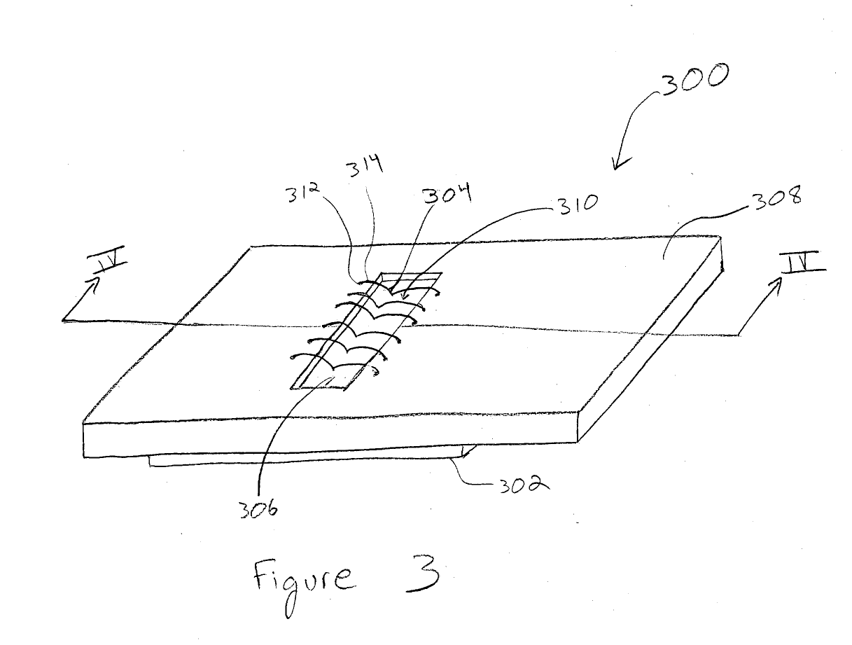

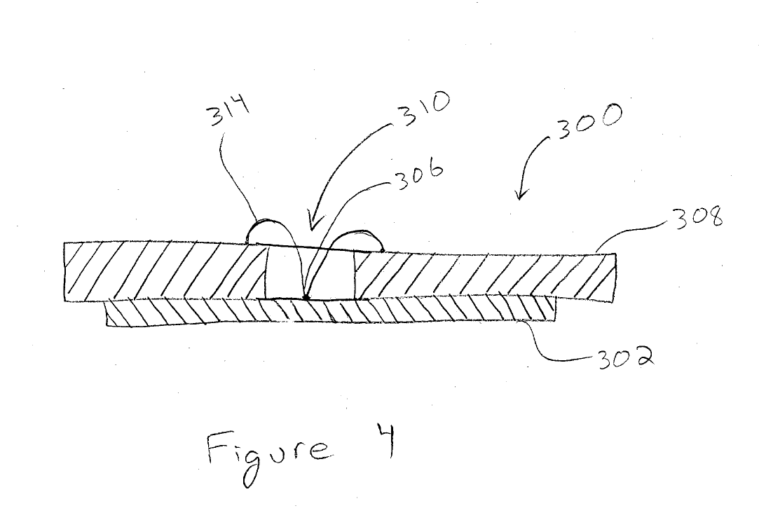

FIGS. 3 and 4 illustrate one embodiment of the invention. An electronic component package 300 is illustrated as including a die 302 and a substrate 308. The die may be any electronic component. In a preferred embodiment, the die is a memory component. In a further preferred embodiment, the die 302 is an SDRAM die. An SDRAM die, such as a die in a 256 Megabyte device available from Hitachi Elpida Model No. HM5225165BTT/BLTT. The SDRAM die has dimensions of 8.3 mm×15.0 mm. The die includes one or more rows of contacts 304 which extend along the middle of the top face 306 of the rectangular die 302. Although FIG. 3 illustrates a die with six contacts, the actual number of contacts may vary according to design requirements. For example, the above-described SDRAM die from Hitachi includes 27 contacts. The contacts may be provided in the form of pads for facilitating soldering of the wire leads.

The substrate 308 is mounted on the top face 306 of the die 302. The mounting of the substrate 308 onto the die 302 is preferably achieved through a non-conductive, high temperature adhesive. Examples of such adhesives include non-conductive epoxy or cyanate ester.

The substrate is provided with a cutout 310 through which the top face 306 of the die 302 is exposed. The cutout 310 is sized and overlayed to expose the contacts 304 of the die 302. The configuration illustrated in FIG. 3 includes a substrate 308 with a rectangular cutout 310. However, other configurations may include cutouts of various shapes and sizes. Preferably, the perimeter of the cutout is proximate to the outline of the contacts 304 of the die 302. For example, a spacing of 1-2 mm should be maintained between the contacts 304 and the perimeter of the cutout 302.

The substrate 308 is provided with a set of contacts 312 on its surface. The contacts 312 correspond to the contacts 304 on the top face of the die 302. Preferably, the contacts 312 of the substrate are proximate to the perimeter of the cutout 310. For example, in a preferred embodiment, the contacts 312 of the substrate 308 are positioned approximately 0.12-0.25 mm from the perimeter of the cutout 310.

Wire leads 314 can now be used to provide electrical connection between the die and the contacts 312 of the substrate 308. Wire leads 314 can be connected to the contacts 304, 312 through ultrasonic or wireball wirebonding, for example. The wire leads 314 may be of a selected gauge to satisfy design requirements such as bus speed, for example.

By placing the substrate on the top face of the die and by providing a cutout to expose the contacts of the die, the length of the wire leads is significantly shortened. The wires are no longer required to extend beyond the edge of the die. As seen clearly in FIGS. 3 and 4, the wires are only required to extend to the contacts on the substrate. Thus, inductance and resistance due to wire length is significantly reduced. Further, the risk of shorting due to sweeping is essentially eliminated.

The illustrated embodiment includes a die and a substrate with a cutout. In other embodiments, the substrate may be mounted to a package, with short leads extending from the perimeter of the substrate to the package. In other embodiments, the die may directly engage a package. In this configuration, the package engages the top face of the die, and the package is provided with a cutout for exposing the contacts of the die. In this regard, the package serves as a substrate.

Thus, the disclosed embodiments of the present invention allow for the use of wire leads while eliminating the disadvantages associated with long wire leads.

While preferred embodiments and methods have been shown and described, it will be apparent to one of ordinary skill in the art that numerous alterations may be made without departing from the spirit or scope of the invention. Therefore, the invention is not limited except in accordance with the following claims.

We claim:

1. An electronic component package, comprising:
a die having a top face with set of contacts;
a substrate having a cutout therein, said substrate being mounted on said top face, and said cutout overlaying said set of contacts; and
wire leads extending from said set of contacts, at least partially through said cutout, to said substrate.

2. The package according to claim 1, wherein said set of contacts is positioned along a central region of said die.

3. The package according to claim 2, wherein said cutout overlays said central region.

4. The package according to claim 1, wherein said cutout is rectangular.

5. The package according to claim 1, wherein said wire leads extend to said substrate and contact said substrate proximate to said cutout.

6. The package according to claim 5, further comprising:
a set of electrical paths extending from said wire leads through said substrate for providing communicative path between said die and an external component.

7. The package according to claim 1, wherein said die includes a memory component.

8. The package according to claim 7, wherein said memory component includes SDRAM.

9. The package according to claim 8, wherein said set of contacts is positioned along a central region of said die.

10. The package according to claim 9, wherein said cutout overlays said central region.

11. The package according to claim 8, wherein said cutout is rectangular.

12. The package according to claim 8, wherein said wire leads extend to said substrate and contact said substrate proximate to said cutout.

13. The package according to claim 12, further comprising:
a set of electrical paths extending from said wire leads through said substrate for providing communicative path between said die and an external component.

14. A method of forming an electronic component package, comprising:
mounting a substrate on a top face of a die, said top face having set of contacts, said substrate having a cutout therein, said cutout overlaying said set of contacts; and
extending wire leads from said set of contacts, at least partially through said cutout, to said substrate.

15. The method according to claim 14, wherein said set of contacts is positioned along a central region of said die.

16. The method according to claim 15, wherein said cutout overlays said central region.

17. The method according to claim 14, wherein said cutout is rectangular.

18. The method according to claim 14, wherein said wire leads extend to said substrate and contact said substrate proximate to said cutout.

19. The method according to claim 18, further comprising:
a set of electrical paths extending from said wire leads through said substrate for providing communicative path between said die and an external component.

20. The method according to claim 14, wherein said die includes a memory component.

21. The method according to claim 20, wherein said memory component includes SDRAM.

22. The method according to claim 21, wherein said set of contacts is positioned along a central region of said die.

23. The method according to claim 22, wherein said cutout overlays said central region.

24. The method according to claim 21, wherein said cutout is rectangular.

25. The method according to claim 21, wherein said wire leads extend to said substrate and contact said substrate proximate to said cutout.

26. The method according to claim 25, further comprising:
a set of electrical paths extending from said wire leads through said substrate for providing communicative path between said die and an external component.
